(19) United States
(12) Patent Application Publication
(10) Pub. No.: US 2011/0128028 A1
(43) Pub. Date: Jun. 2, 2011

(54) PROBE CARD, MAINTENANCE APPARATUS AND METHOD FOR THE SAME

(76) Inventors: Chin-Yi Lin, Hsinchu Hsiang (TW); Ching-Huang Yang, Hsinchu Hsiang (TW); Chien-Chou Wu, Hsinchu Hsiang (TW); Shih-Chang Wu, Hsinchu Hsiang (TW); Che-wei Lin, Hsinchu Hsiang (TW); Tsung-Hsuan Yen, Hsinchu Hsiang (TW); Tzu-Chun Chen, Hsinchu Hsiang (TW); Tsung-Yi Chen, Hsinchu Hsiang (TW)

(21) Appl. No.: 12/954,913

(22) Filed: Nov. 29, 2010

(30) Foreign Application Priority Data
Dec. 1, 2009 (TW) 098141045

(51) Int. Cl. G01R 31/00

(52) U.S. Cl. 324/756.03; 324/756.01

(57) ABSTRACT

A maintenance apparatus and a maintenance method for a probe card are provided. The maintenance apparatus includes a first supporting member, a second supporting member, a first clamping member, a second clamping member, and a plurality of locking units. In the maintenance method, the first supporting member and the second supporting member are initially positioned underneath below the two sides of a positioning slice, respectively, and then the first clamping member and the second clamping member are each disposed on the first supporting member and the second supporting member, respectively. First clamping member and first supporting member, and second clamping member and second supporting member are secured together respectively by locking units. Thus two sides of positioning slice are secured tightly and the positioning slice is well fastened. A probe card is also provided. The probe card includes a guide slot having a size corresponding to that of maintenance apparatus.

### FIELD OF INVENTION

The invention relates to a maintenance apparatus and a maintenance method for a probe card, especially relates to a maintenance apparatus and a maintenance method for fastening a positioning slice of the probe card. The invention also relates to a probe card, especially relates to a probe card having a guide slot that is corresponding to a maintenance apparatus.

### BACKGROUND OF THE INVENTION

In the conventional art, a plurality of probe pins on a probe card is often needed to be maintained or replaced due to losses or damages. During the detachment of the probe card for maintenance or replacement, two guide plates of the probe card are needed to be separated in advance, and the probe pins positioned and disposed between the two guide plates are taken off. For providing supporting and a buffer space for the probe pins, the probe pins are inserted into the pin holes of a positioning slice. The conventional positioning slice is not a fixed or stationary element, so that the removing of some of the probe pins from the positioning slice may easily causes the positioning slice itself to be moved or rollover, thereby causing other probe pins to be also detached. Therefore, the time spent on the manually re-inserting and positioning of the probe pins, and the cost for replacing the damaged probe pins are increased.

At least for that reason, an improving vertical probe card shown in Taiwanese Patent No. 1299085 is provided. Please refer to FIG. 1 and FIG. 2. The vertical probe card 1 includes a first guide plate 11, a second guide plate 12, a positioning slice 13, and a plurality of probe pins 14. A plurality of pin holes 15 is disposed on the first and second guide plate 11, 12 and the positioning slice 13. The probe pins 14 are inserted into the pin holes 15, which are being used during assembly. An inwardly recessed containing space 16 is formed in the first guide plate 11. Two bumps 17 are each disposed on the two sides of the containing space 16, respectively. By using a plurality of screws 18, the two sides of the positioning slice 13 are each fastened on the two bumps respectively, so as to maintain a pre-determined height between the positioning slice 13 and the bottom of the containing space 16. The positioning slice 13 is a flexible, thin insulating piece having a plurality of pin holes 15. During the assembly of the probe card 1, the probe pins 14 are positioned and inserted into the pin holes 15 of the positioning slice 13, and passed through the corresponding pin holes 15 of the first guide plate 11, which are in the bottom of the containing space 16. After that, the guide plate 12 is stacked and fixed on the first guide plate 11, so as to allow the top end of the probe pins 14 to pass through the corresponding pin holes 15 of the second guide plate 12. After assembly is finished, the probe pin 14 is protruded from one side of the second guide plate 12 which is facing away from the positioning slice 13, and electrically connected with a plurality of contacts of a space transformer (not shown). The space transformer is electrically connected with a printed circuit board (PCB, not shown) by wire bonding or reflow soldering technology. Furthermore, accordingly, the probe pins 14 are also protruded from the side of the first guide plate 11 which is facing away from the positioning slice 13, and to form contact with a metal soldering pad of a device under test for electrical transmitting or measuring.

Because of the pre-determined height between the positioning slice 13 and the containing space 16, an external force applied thereon can be absorbed by the deformation or due to the flexibility of the probe pins 14. In addition, besides capability for providing support function, the positioning slice 13 also provides structural flexibility. Because the positioning slice 13 is made of transparent or translucent material, the positioning operation between the probe pins 14 and the pin holes 15 can be easily performed during assembly of the probe card 1.

However, due to the trend for increasing complexity of probe card structure and the increasing demand for better electrical transmission quality, therefore, a plurality of auxiliary electrical components is disposed around the positioning slice 13 to maintain the transmitting quality of the signals. Therefore, the two bumps 17 of the second guide plate 12 are thus needed to be removed for saving space to accommodate for the auxiliary electrical components. Thus, during the maintenance of the probe card 1, the positioning slice 13 is suspended and taken out of operation. For that reason, the detachment process of the probe pins 14 leads to the rollover and movement of the positioning slice 13 so as to possibly result in the damages of the probe pins 14 or the need for manually re-inserting of the probe pins 14, and thereby the time spent on the manually re-inserting of the probe pins 14 takes longer.

### SUMMARY OF THE INVENTION

One aspect of the present invention is to resolve the issues relating to the difficulty in the maintenance of the probe card, which is resulted from not fastening the positioning slice of the probe card accurately. Therefore, the present invention provides a probe card, and a maintenance apparatus and a maintenance method for the probe card. By the present invention, the positioning slice can be fastened more precisely and accurately, so that the maintenance of the probe card is not negatively influenced by the movement of the positioning slice.

To achieve the foregoing and other aspects, a maintenance method for a probe card is provided. The maintenance method is configured to cooperate with a maintenance apparatus of the present invention. The maintenance apparatus includes a first supporting member, a first clamping member, a second supporting member, a second clamping member, and a plurality of locking units. The maintenance method includes the following steps. The first supporting member and the second supporting member are each initially positioned underneath the bottom of the two side edges of the positioning slice, respectively, and the first clamping member and the second clamping member are each disposed on the first supporting member and the second supporting member, respectively. The first clamping member and the first supporting member, and the second clamping member and the second supporting member are secured together by the locking units, respectively, so as to clamp the two side edges of the positioning slice and thereby fastening and fixing the positioning slice. The probe card of the invention has at least a guide slot which is corresponding to the first clamping member and/or the second clamping member.

The positioning slice can be positioned accurately and precisely by the maintenance apparatus of the invention, so that the damages of undamaged probe pins resulting from the dislocation of the positioning slice can be avoided during the replacement of probe pins. Furthermore, the maintenance method of the invention can save on the cost and time consumed during maintenance.

The above and other aspects, features, and advantages of the present invention will become more apparent from the following detailed description when taken in conjunction with the accompanying drawings.

### BRIEF DESCRIPTION OF THE DRAWINGS

FIG. 1 is a diagram which shows an exploded view of a plurality of conventional vertical probe pins.

FIG. 2 is a diagram which shows a sectional view of the conventional vertical probe pins.

FIG. 3 is a diagram which shows an exploded view of a maintenance apparatus and a probe card of an embodiment of the present invention.

FIG. 4 is a diagram which shows the exploded view of the maintenance apparatus and the probe card of another embodiment of the present invention.

FIG. 5-1 to FIG. 5-3 show the procedures of a maintenance method of an embodiment of the present invention.

FIG. 6-1 to FIG. 6-3 show the procedures of the maintenance method of another embodiment of the present invention.

### DETAILED DESCRIPTION OF THE INVENTION

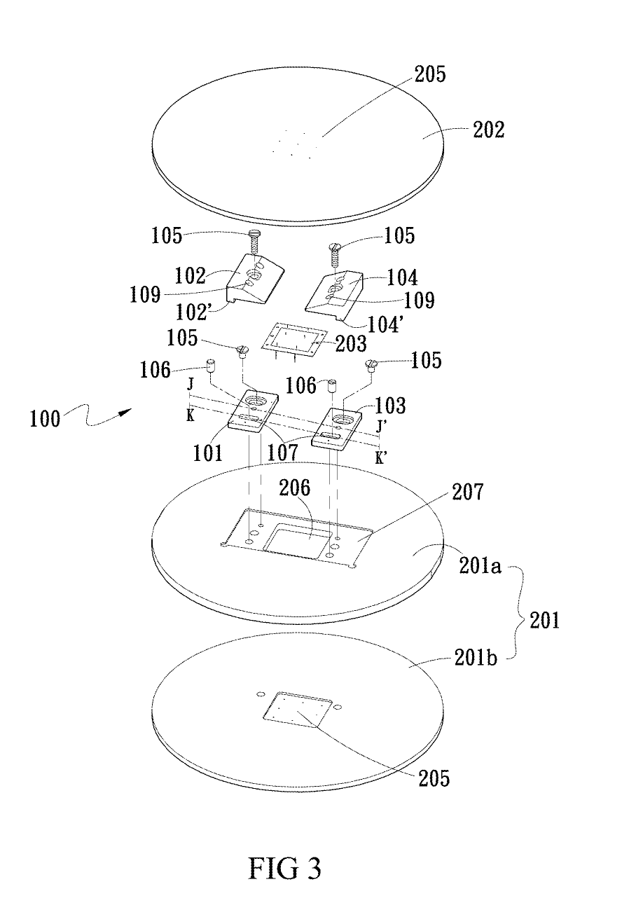

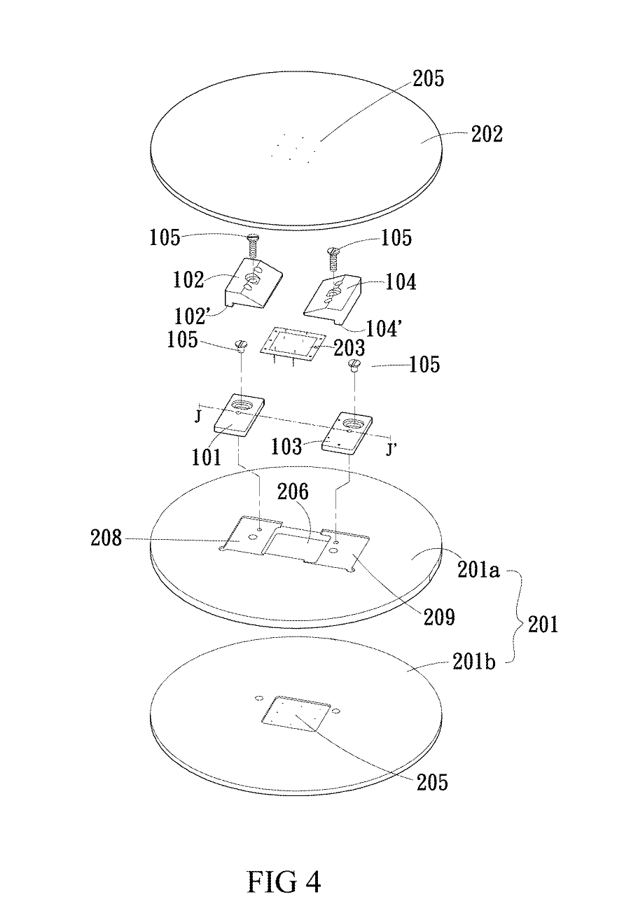

The present invention provides a maintenance method for a probe card and a maintenance apparatus 100 used in the maintenance method. Please refer to FIG. 3 and FIG. 4. FIG. 3 and FIG. 4 show the exploded views of the maintenance apparatus 100 and the probe card of two embodiments of the present invention, respectively. The maintenance apparatus 100 includes a first supporting member 101, a first clamping member 102, a second supporting member 103, a second clamping member 104, and a plurality of locking units 105. For the sake of brevity, the probe card, the maintenance apparatus 100, and the maintenance method are described together in the following description.

The probe card includes a first guide plate 201, a second guide plate 202, a positioning slice 203, and a plurality of probe pins 204. The first guide plate 201, the second guide plate 202, and the positioning slice 203 all have a plurality of the pin holes 205. The positioning slice 203 is disposed between the first guide plate 201 and the second guide plate 202. During assembly, the pin holes 205 of the first guide plate 201, the second guide plate 202, and positioning slice 203 are appropriately configured so as to be corresponding to each other, in order to be properly inserted by the probe pins 204. An inwardly recessed containing space 206 is disposed in the first guide plate 201 and the pin holes 205 of the first guide plate 201 are formed on the bottom of the containing space 206. The probe pins 204 can be inserted individually into the pin holes 205 of the positioning slice 203 for being positioned in advance, and then inserted into the corresponding pin holes 205 in the bottom of the containing space 206. During the stacking of the second guide plates 202 during assembly, the other end of each of the probe pins 204 is inserted into the corresponding pin hole 205 of the second guide plate 202. In some of the embodiments of the probe cards, the first guide plate 201 is formed by stacking a middle die 201a and a lower die 201b. The second guide plate 202 may be an upper die of a probe head. The positioning slice 203 is flexible and made of transparent or translucent material, so that the probe pins 204 are easily positioned with the pin holes 205 of the lower die 201b.

During the replacement and maintenance of the probe pins 204 with the removing of the second guide plate 202, which was originally stacked on the first guide plate 201, the positioning slice 203 is being supported by the probe pins 204, thus to be suspended and substantially parallel to the first guide plate 201. Furthermore, there is a fixed height between the positioning slice 203 and the first guide plate 201. Therefore, the positioning slice 203 is needed to be fastened for the maintenance or replacement of the probe pins 204 in a more convenient manner. In the maintenance method of the present invention, the first supporting member 101 and the second supporting member 103 are each positioned under at the bottom of the two side edges of the positioning slice 203, respectively. Thereafter, the first clamping member 102 and the second clamping member 104 are each disposed on the first supporting member 101 and the second supporting member 103 respectively, and the first clamping member 102 and the second clamping member 104 are above the positioning slice 203 and each pressing against the two opposite sides of the positioning slice 203, respectively. The first clamping member 102 and the first supporting member 101, and the second clamping member 104 and the second supporting member 103 are secured together by the locking units 105, so as to clamp the two side edges of the positioning slice 203, and to fasten the positioning slice 203, and thereby allowing the probe pins to be replaced or maintained conveniently.

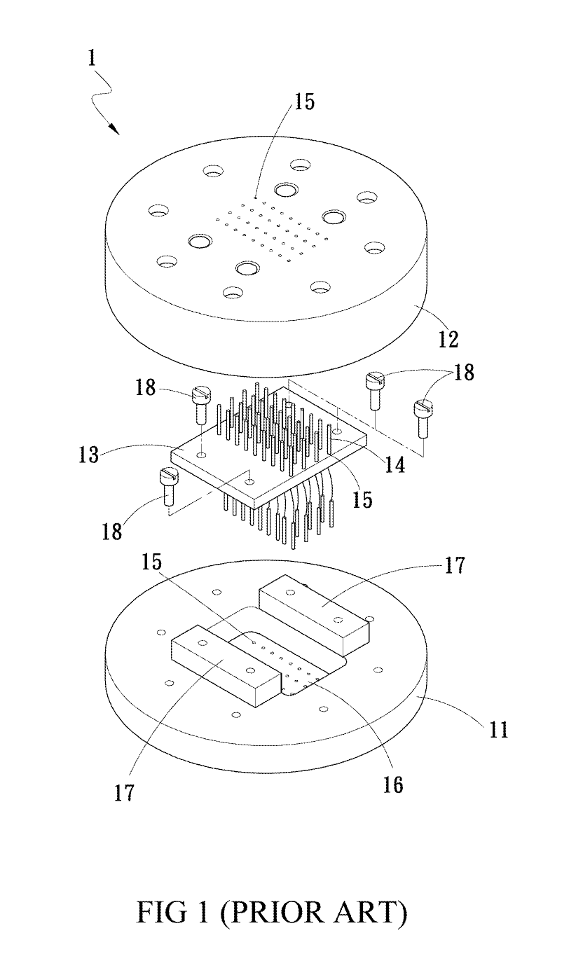

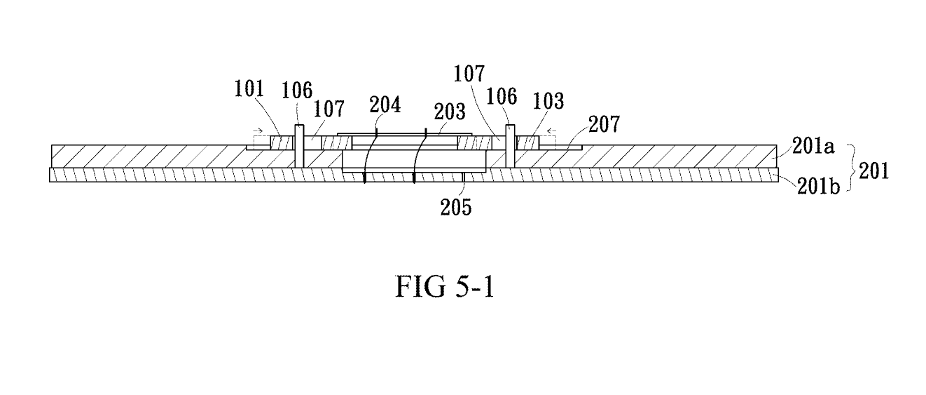

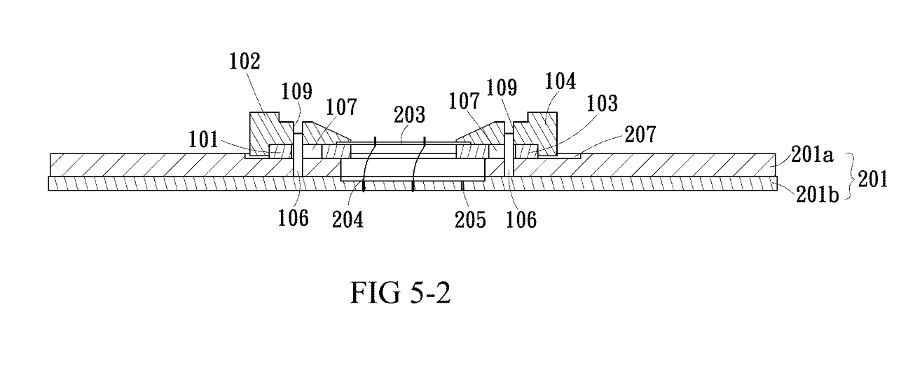

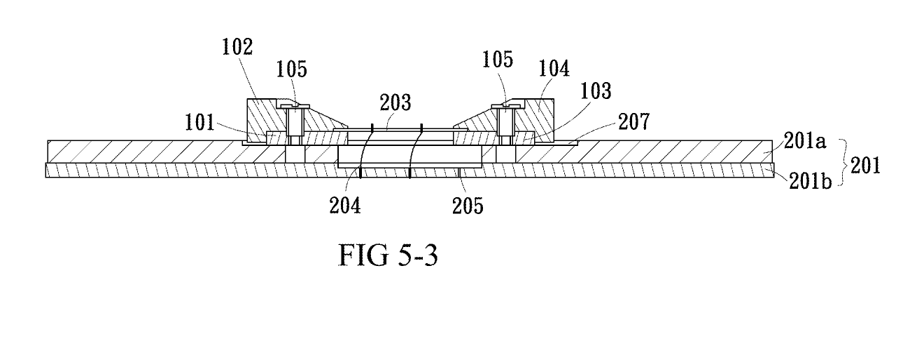

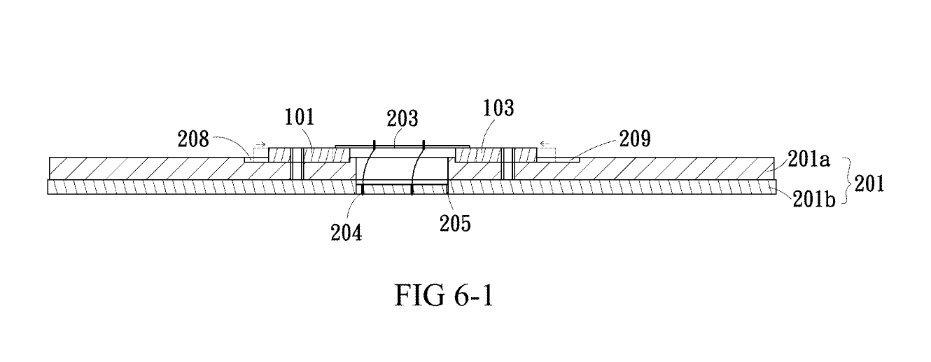

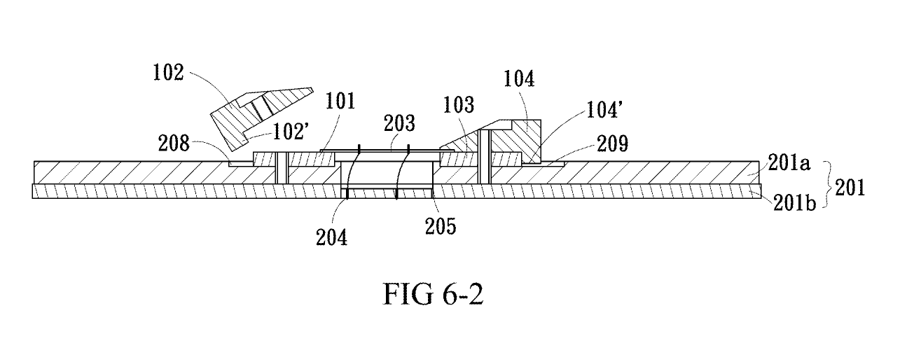

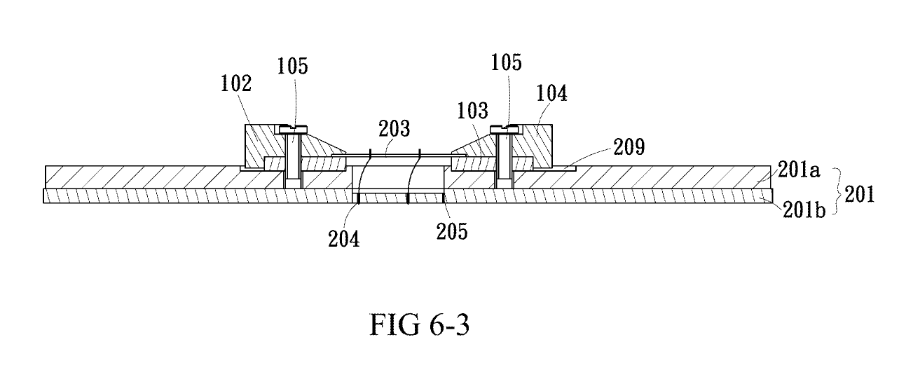

Please refer to FIG. 5-1, FIG. 6-1, FIG. 3, and FIG. 4. The first supporting member 101 and the second supporting member 103 are each positioned under the bottom of the positioning slice 203 at the two side edges of the positioning slice 203. Because the fixed height is set between the positioning slice 203 and the first guide plate 201, the first supporting member 101 and the second supporting member 103 can be moved and positioned under the bottom of the positioning slice 203 at the two side edges of the positioning slice 203 if their (the first supporting member 101 and the second supporting member 103) thicknesses are smaller than or equal to the fixed height, so as to support the positioning slice 203. Interference with the probe pins 204 should be avoided during the movement of the first and second supporting members 101, 103 to the positioning points on the bottom of the positioning slice 203.

FIG. 5-1 and FIG. 6-1 each shows KK′ and JJ′ sectional views of FIG. 3 and FIG. 4 respectively, and show a plurality of embodiments of the positioning method of the first and second supporting members 101, 103. In order to prevent the first and second supporting members 101, 103 from interfering with the probe pins 204 during movement of the first and second supporting members 101, 103, a plurality of stoppers 106 is disposed to restrict the movement or dislocation range of the first and second supporting members 101, 103. As shown in a first embodiment in FIG. 5-1, the stoppers 106 are configured to be inserted in a pre-determined location of the first guide plate 201, for example, being inserted into a plurality of holes disposed on the guide slot 207. A slide hole 107 having dimensions corresponding to the width of the stopper 106 is formed on each of the first supporting member 101 and the second supporting member 103. By using the slide holes 107, the first and second supporting members 101, 103 enclose the stoppers 106. Furthermore, by means of the interference between the side walls of the slide holes 107 and the stoppers 106, the first supporting member 101 and the second supporting member 103 are each positioned under the bottom of the positioning slice 203 at the two sides. The order of the positioning sequence is not limited to that being described in the above-described first embodiment. The stoppers 106 can be passed through the first and second supporting members 101, 103, and inserted in the first guide plate 201. Furthermore, after being positioned, the first and second supporting members 101, 103 are secured on the first guide plate 201 by using at least a locking unit 105. In order to restrict the sliding direction of the first and second supporting members 101, 103 on the first guide plate 201 and prevent the first and second supporting members 101, 103 from being inadvertently colliding with the probe pins 204, a guide slot 207 having dimensions corresponding to the size of the first and second supporting members 101, 103 is disposed on the first guide plate 201. Therefore, the first and second supporting members 101, 103 can slide along the side edges of the guide slot 207 in a parallel direction.

FIG. 6-1, corresponding to FIG. 4, shows a second embodiment of present invention illustrating the restriction for the movement of the first and second supporting members 101, 103. In this embodiment, a first guide slot 208 and a second guide slot 209, which are corresponding to the first supporting member 101 and the second supporting member 103, respectively, are disposed on the first guide plate 201. Therefore, the first supporting member 101 and the second supporting member 103 are each positioned and slidably moved under the constraints of the first guide slot 208 and the second guide slot 209, respectively. For example, the first supporting member 101 is disposed on the first guide slot 208 in advance, pushed into an edge of the guide slot 208 adjacent to the positioning slice 203, and stopped by the edge of the guide slot 208. Thus, the first supporting member 101 is located and positioned under the bottom of one side edge of the positioning slice 203. After being positioned, the first and second supporting members 101, 103 can be secured by at least a locking unit 105, respectively.

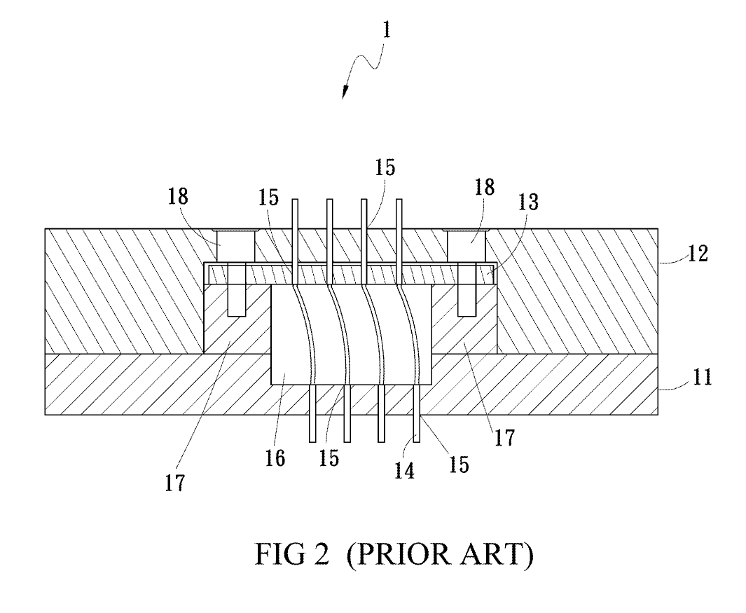

After being positioned, the first clamping member 102 and the second clamping member 104 are each disposed on the first supporting members 101 and the second supporting members 103 respectively, so that the two sides of the positioning slice 203 are each clamped between the first supporting member 101 and the first clamping member 102, and between the second supporting member 103 and the second clamping member 104, as shown in FIG. 5-2 and FIG. 6-2, respectively. In the first embodiments shown in FIG. 5-2, a plurality of through holes 109 corresponding to the size of the stopper 106 is formed on the first and second clamping member 102, 104. By using these through holes 109, the first and second clamping member 102, 104 can enclose the stoppers 106 and be positioned, and are disposed on the first and second supporting member 101, 103 respectively. In the second embodiments shown in FIG. 6-2, each of the first and second clamping member 102, 104 includes a guide portion 102′ and a guide portion 104′, respectively. The guide portions 102′, 104′ are abutting against the sides of the first and second supporting member 101, 103 which are away from the positioning slice 203, and are disposed and located appropriately on the first and second supporting member 101, 103, respectively.

As shown in FIG. 5-3, which is corresponding to section sectional view of FIG. 3, and FIG. 6-3, at least one locking unit 105 is used to lock tightly the first clamping member 102 and the second clamping member 104 on the first supporting member 101 and the second supporting member 103, respectively. Therefore, the positioning slice 203 is clamped, fastened and prevented from moving. The locking units 105 can be a plurality of screws. In FIG. 6-3, the locking units 105 are passed through the first and the second supporting members 101, 103, respectively, and lock the first supporting member 101, the first clamping member 102, the second supporting member 103, and the second clamping member 104 securely on the first guide plate 201.

In this embodiment, the thicknesses of the first and second clamping members 102, 104 are gradually increased along a direction away from the positioning slice 203. In other words, replacing the probe pins 204 in the outer edge of the positioning slice 203 becomes more convenient due to the thinner thickness of the first and second clamping members 102, 104 at the respective clamping locations of the positioning slice 203, so as to prevent mutual interference, and therefore, structural strength can be enhanced because of the thicker thickness of the first and second clamping members 102, 104 away from the respective clamping locations of the positioning slice 203.

The maintenance method of the present invention can further include a preparation step of disposing a protecting cover (not shown) on the positioning slice 203 to prevent the positioning slice 203 and the probe pins 204 from being damaged during the positioning of the positioning slice 203. After the positioning slice 203 is positioned, the protecting cover is detached or removed, and the replacement or maintenance process of the probe pins 204 can be then performed.

To sum up, by using the maintenance apparatus of the invention, the positioning slice 203 is fastened securely and accurately. Thus, movement of the positioning slice 203, or damage and re-inserting of the probe pins 204 resulting from the dislocation, tipping, or rollover of the positioning slice 203, can thereby be avoided.

Although the description above contains many specifics, these are merely provided to illustrate the invention and should not be construed as limitations of the invention's scope. Thus it will be apparent to those skilled, in the art that various modifications and variations can be made in the system and processes of the present invention without departing from the spirit or scope of the invention.

What is claimed is:

1. A maintenance method for a probe card, the probe card comprising a positioning slice and a plurality of probe pins is inserted in the positioning slice, the maintenance method comprising:
positioning each of a first supporting member and a second supporting member under the bottom of the positioning slice at two sides of the positioning slice, respectively; and
locking each of a first clamping member and a second clamping member on the first supporting member and the second supporting member, respectively, so as to clamp each of the two sides of the positioning slice between the first supporting member and the first clamping member and between the second supporting member and the second clamping member, respectively and to fasten the positioning slice.

2. The maintenance method of claim 1, wherein the probe card further comprising a guide plate, the positioning slice and the guide plate are arranged in parallel, and a fixed height is set between the position slice and the guide plate, so that the first supporting member and the second supporting member each having a thickness smaller than or equal to the fixed height are positioned under the bottom of the positioning slice.

3. The maintenance method of claim 2, wherein a stopper is inserted in each of the two opposite sides of the positioning slice in the guide plate, a slide hole comprising dimensions corresponding to the size of the stopper is formed in each of the first supporting member and the second supporting member, respectively, the first supporting member and the second supporting member enclose the stoppers and are configured to be moved and positioned by using the slide holes.

4. The maintenance method of claim 3, wherein by using at least a locking unit, each of the first supporting member and the second supporting member is locked on the guide plate after being positioned on the bottom at two side edges of the positioning slice, respectively.

5. The maintenance method of claim 3, wherein a through hole corresponding to the size of the stopper is formed in each of the first clamping member and the second clamping member, and by using the through hole, each of the first clamping member and the second clamping member encloses the stopper and is disposed on the first supporting member and the second supporting member, respectively.

6. The maintenance method of claim 2, wherein a guide slot is disposed in the guide plate, and the first supporting member and the second supporting member are configured to slide in parallel along the side edges of the guide slot.

7. The maintenance method of claim 2, wherein a first guide slot and a second guide slot are disposed in the guide plate, and each of the first supporting member and the second supporting member is configured to slide into the edge portions of the first guide slot and the second guide slot and be positioned, respectively.

8. The maintenance method of claim 2, wherein by using at least a locking unit, each of the first supporting member and the second supporting member is locked on the guide plate after being positioned on the bottom at two sides of the positioning slice, respectively.

9. The maintenance method of claim 1, further comprising a preparation step of disposing a protecting cover on the positioning slice to prevent the positioning slice and the probe pins from being damaged.

10. A maintenance apparatus for a probe card, the probe card comprising a positioning slice and a plurality of probe pins is inserted in the positioning slice, the maintenance apparatus comprising:
two supporting members, the two supporting members each positioned under the bottom at two sides of the positioning slice, respectively;
two clamping members, the two clamping members each disposed on the two supporting members and pressing two side edges of the positioning slices, respectively; and
a plurality of locking units, the locking units configured to lock the two supporting members and the two clamping members so as to fasten the positioning slice.

11. The maintenance apparatus of claim 10, wherein the probe card further comprising a guide plate, and the thickness of each of the two supporting members is smaller than or equal to the height between the positioning slice and the guide plate.

12. The maintenance apparatus of claim 11, further comprising a plurality of stoppers, and the stoppers are configured to be fixed on the guide plate, wherein each of the two supporting members comprises a slide hole corresponding to the size of the stopper, and by using the slide hole each of the two supporting members encloses the stopper and is configured to be moved and positioned.

13. The maintenance apparatus of claim 12, wherein each of the two clamping members comprises a through hole corresponding to the size of the stopper, and each of the two clamping members encloses the stopper and is disposed on the two supporting members, respectively, by using the through hole.

14. The maintenance apparatus of claim 10, wherein the thickness of the two clamping members is gradually increasing from a clamping location of the positioning slice to away from the positioning slice.

15. A probe card, comprising:
a first guide plate, the first guide plate comprising an inwardly recessed containing space, at least one guide slot disposed adjacent to the containing space and having the size corresponding to a maintenance apparatus for a probe card, and the maintenance apparatus positioned in the first guide plate by the guide slot;
a second guide plate;
a positioning slice, disposed between the first guide plate and the second guide plate; and
a plurality of probe pins, the probe pins positioned in the containing space by using the positioning slice, and the probe pins are inserted between the first guide plate and the second guide plate.

16. The probe card of claim 15, wherein a plurality of holes is disposed on the guide slot, a plurality of stoppers of the maintenance apparatus is configured to be inserted in the holes to position the maintenance apparatus on the first guide plate.

17. The probe card of claim 15, wherein the first guide plate is formed by stacking a middle die and a bottom die together.
